(19) United States
(12) Patent Application Publication
(10) Pub. No.: US 2022/0156556 A1
(43) Pub. Date: May 19, 2022

(54) SPIKING NEURAL NETWORK CIRCUIT

(71) Applicant: Electronics and Telecommunications Research Institute, Daejeon (KR)

(72) Inventors: Kwang IL OH, Daejeon (KR); Tae Wook KANG, Daejeon (KR); Sung Eun KIM, Daejeon (KR); Hyuk KIM, Daejeon (KR); Hyung-IL PARK, Daejeon (KR); Jae-Jin LEE, Daejeon (KR)

(73) Assignee: Electronics and Telecommunications Research Institute, Daejeon (KR)

(21) Appl. No.: 17/446,685

(22) Filed: Sep. 1, 2021

(30) Foreign Application Priority Data
Nov. 18, 2020 (KR) 10-2020-0154298
Mar. 11, 2021 (KR) 10-2021-0031907

(51) Int. Cl. G06N 3/04; G06N 3/063; H03K 19/20

(52) U.S. Cl. CPC G06N 3/049; H03K 19/20; G06N 3/0635

(57) ABSTRACT

Disclosed is a spiking neural network circuit, which includes an axon circuit that generates an input spike signal, a first synapse zone and a second synapse zone each including one or more synapses, wherein each of the synapses is configured to perform an operation based on the input spike signal and each weight, and a neuron circuit that generates an output spike signal based on operation results of the synapses. The input spike signal is transferred to the first synapse zone and the second synapse zone through a tree structure, and each of branch nodes of the tree structure includes a driving buffer.

### CROSS-REFERENCE TO RELATED APPLICATIONS

This application claims priority under 35 U.S.C. § 119 to Korean Patent Application Nos. 10-2020-0154298, filed on Nov. 18, 2020, and 10-2021-0031907, filed on Mar. 11, 2021, respectively, in the Korean Intellectual Property Office, the disclosures of which are incorporated by reference herein in their entireties.

### BACKGROUND

Embodiments of the present disclosure described herein relate to a spiking neural network circuit, and more particularly, relate to a spiking neural network circuit including a hierarchical transfer structure of a spike signal.

Artificial neural networks (ANNs) may process data or information in a manner similar to biological neural networks. Unlike a perceptron-based neural network or a convolution-based neural network, a signal of a specific level is not transferred in a spiking neural network, but a spike signal in the form of a pulse that toggles for a short period of time may be transferred.

The spiking neural network may be implemented using a semiconductor device. Recently, as the number of neurons integrated in the spiking neural network increases as the spiking neural network is used in various fields, the number of synapses connected to the neurons also increases. As the number of synapses receiving one spike signal increases, power consumption by the spiking neural network increases.

### SUMMARY

Embodiments of the present disclosure provide a spiking neural network circuit including a hierarchical transfer structure of a spike signal.

According to an embodiment of the present disclosure, a spiking neural network circuit includes an axon circuit that generates an input spike signal, a first synapse zone and a second synapse zone each including one or more synapses, wherein each of the synapses is configured to perform an operation based on the input spike signal and each weight, and a neuron circuit that generates an output spike signal based on operation results of the synapses, the input spike signal is transferred to the first synapse zone and the second synapse zone through a tree structure, and each of branch nodes of the tree structure includes a driving buffer.

According to an embodiment, the tree structure may include OR gates configured to output an enable signal to the corresponding driving buffer.

According to an embodiment, the tree structure may include a first layer, a second layer, and a first OR gate, the first layer may include a first driving buffer that receives the input spike signal, and first OR gate may output a first enable signal to the first driving buffer based on enable signals output from the second layer.

According to an embodiment, the second layer may include a second driving buffer including an input terminal connected to an output terminal of the first driving buffer and an output terminal connected to the first synapse zone, and a third driving buffer including an input terminal connected to the output terminal of the first driving buffer and an output terminal connected to the second synapse zone, and the tree structure may include a second OR gate that outputs a second enable signal to the second driving buffer, and a third OR gate that outputs a third enable signal to the third driving buffer.

According to an embodiment, the second OR gate may receive weights of synapses of the first synapse zone, and may output the second enable signal based on the weights of the synapses of the first synapse zone.

According to an embodiment, the second driving buffer may be activated or deactivated in response to the second enable signal, when the second driving buffer is activated, the second driving buffer may transfer the input spike signal received from the first driving buffer to the synapses of the first synapse zone, and when the second driving buffer is deactivated, the second driving buffer may transfer a signal corresponding to a first logic to the synapses of the first synapse zone.

According to an embodiment, a first synapse of the first synapse zone may include a current source which outputs a current signal based on a weight of the first synapse and a transistor which receives the current signal, and an output terminal of the second driving buffer may be connected to a gate of the transistor of the first synapse.

According to an embodiment, the second driving buffer may transfer the input spike signal to the gate of the transistor of the first synapse in response to the second enable signal, and the transistor may be turned on in response to the input spike signal and may output the current signal to the neuron circuit.

According to an embodiment, the first OR gate may output the first enable signal to the first driving buffer, based on the second enable signal and the third enable signal, the first driving buffer may be activated or deactivated in response to the first enable signal, when the first driving buffer is activated, the first driving buffer may transfer the input spike signal to the second driving buffer and the third driving buffer, and when the first driving buffer is deactivated, the first driving buffer may transfer a signal corresponding to a first logic to the second driving buffer and the third driving buffer.

According to an embodiment of the present disclosure, a spiking neural network circuit includes an axon circuit that generates an input spike signal, synapse zones each including one or more synapses, wherein each of the synapses is configured to perform an operation based on the input spike signal and each weight, and a neuron circuit that generates an output spike signal based on operation results of the synapses, and the input spike signal is selectively transferred to at least some of the synapse zones based on weights of the synapses through a tree structure.

According to an embodiment, each of branch nodes of the tree structure may include a driving buffer which receives the input spike signal from a driving buffer of an upper layer and transfers the input spike signal to driving buffers of a lower layer in response to an enable signal, and the tree structure may include OR gates which generate the corresponding enable signal to the corresponding driving buffer.

According to an embodiment, the tree structure may include a first layer and a second layer, the second layer may include a first branch node corresponding to a first synapse zone of the synapse zones and a second branch node corresponding to a second synapse zone of the synapse zones, the first branch node may include a first driving buffer which transfers the input spike signal transferred from the first layer to the first synapse zone in response to a first enable signal, and the first enable signal may be based on weights of synapses of the first synapse zone.

According to an embodiment, the first enable signal may correspond to a logic low in response to weights of all synapses in the first synapse zone being ‘0’, and may correspond to a logic high in response to at least one of the weights of the synapses in the first synapse zone being non-zero.

According to an embodiment, the first driving buffer may be deactivated in response to the first enable signal corresponding to the logic low, and may transfer the input spike signal to the first synapse zone in response to the first enable signal corresponding to the logic high.

According to an embodiment, the second branch node may include a second driving buffer which transfers the input spike signal transferred from the first layer to the second synapse zone in response to a second enable signal, the second enable signal may be based on weights of synapses in the second synapse zone, the first layer may include a third branch node connected to the first branch node and the second branch node, the third branch node may include a third driving buffer which transfers the input spike signal to the first driving buffer and the second driving buffer in response to a third enable signal, and the third enable signal may be based on the first enable signal and the second enable signal.

According to an embodiment, the third enable signal may correspond to a logic high in response to that at least one of the first enable signal and the second enable signal corresponds to the logic high, and may correspond to a logic low in response to that both the first enable signal and the second enable signal correspond to the logic low, and the third driving buffer may be deactivated in response to the third enable signal corresponding to the logic low, and may transfer the input spike signal to the second branch node and the third branch node in response to the third enable signal corresponding to the logic high.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating a spiking neural network circuit according to some embodiments of the present disclosure.

FIG. 2 is a block diagram illustrating synapses connected to one transmission line in more detail, according to some embodiments of the present disclosure.

FIG. 3 is a graph illustrating a change in membrane voltage over time, according to some embodiments of the present disclosure.

FIG. 4 is a diagram illustrating synapses that receive one input spike signal in more detail, according to some embodiments of the present disclosure.

FIG. 5 is a diagram illustrating a hierarchical structure of synapses that receive one input spike signal, according to some embodiments of the present disclosure.

FIG. 6 is a diagram illustrating a synapse zone of FIG. 5 in more detail, according to some embodiments of the present disclosure.

FIG. 7 is a diagram illustrating an operation in which one input spike signal is transferred to a plurality of synapses, according to some embodiments of the present disclosure.

### DETAILED DESCRIPTION

Hereinafter, embodiments of the present disclosure will be described clearly and in detail such that those skilled in the art may easily carry out the present disclosure.

Hereinafter, some embodiments of the present disclosure will be described in more detail with reference to the accompanying drawings. In describing the present disclosure, similar reference numerals will be used for similar elements in the drawings in order to facilitate an overall understanding, and redundant descriptions for similar elements will be omitted.

The present disclosure relates to a circuit implemented in a semiconductor device to perform an operation of a neural network. The neural network of the present disclosure may be an artificial neural network (ANN) capable of processing data or information in a manner similar to a biological neural network. The neural network may include a plurality of layers including artificial neurons similar to biological neurons and synapses connecting the plurality of layers. Hereinafter, a spiking neural network that processes a spike signal having a toggling pulse shape for a short time will be representatively described. However, the circuit according to an embodiment of the present disclosure is not limited to the spiking neural network, and may be used to implement other neural networks.

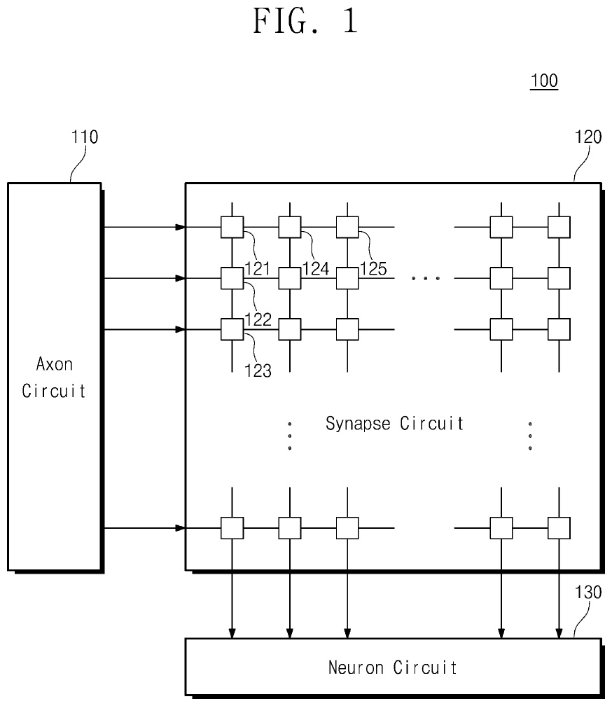

FIG. 1 is a block diagram illustrating a spiking neural network circuit 100, according to some embodiments of the present disclosure. Referring to FIG. 1, the spiking neural network circuit 100 may include an axon circuit 110, a synapse circuit 120, and a neuron circuit 130.

The axon circuit 110 may include axons that generate input spike signals. An axon of the axon circuit 110 may perform a function of outputting a signal to another neuron, similarly to an axon of a biological neural network. For example, each of the axons of the axon circuit 110 may generate an input spike signal based on data or information input to the spiking neural network circuit 100 from the outside. For another example, each of the axons of the axon circuit 110 may receive (feedback) output spike signals output from the neuron circuit 130 depending on the input spike signals transmitted to the synapse circuit 120 earlier and then may generate a new input spike signal based on the output spike signals. The input spike signal may be a pulse signal that toggles for a short time. The axon circuit 110 may generate input spike signals and transmit them to the synapse circuit 120.

The synapse circuit 120 may connect the axon circuit 110 and the neuron circuit 130. The synapse circuit 120 may include a plurality of synapses (e.g., 121, 122, 123, 124, and 125) for determining whether to connect or not and connection strength between axons of the axon circuit 110 and neurons in the neuron circuit 130. Each of the synapses may have a corresponding weight. Each of the synapses may receive the input spike signal, and a weight may be applied to the received input spike signal. For example, the synapses may perform an operation for applying each weight to the received input spike signal. The weight may be a numerical value indicating a correlation between the axon and the neuron described above, a connection strength between the axons of the axon circuit 110 and the neurons of the neuron circuit 130, and a correlation of the (subsequent) neuron of the neuron circuit 130 with respect to the input spike signal. The synapse circuit 120 may output a result of applying a weight to the input spike signals to the neuron circuit 130.

The spiking neural network circuit 100 may include a plurality of layers each including a plurality of neurons. Some synapses of the synapse circuit 120 may indicate a correlation between a first layer and a second layer, and other synapses of the synapse circuit 120 may indicate a correlation between a third layer and a fourth layer. That is, the synapses of the synapse circuit 120 may represent correlations among various layers.

Referring to FIG. 1, the synapses are illustrated to be disposed on a two-dimensional array. The input spike signals may be transmitted in a first direction from the axon circuit 110 to the synapse circuit 120. A result obtained by applying a weight to the input spike signal may be transmitted in a second direction from the synapse circuit 120 to the neuron circuit 130. For example, the first direction and the second direction may be perpendicular to each other. However, unlike the illustration of FIG. 1, the synapses may be arranged on a three-dimensional array.

The neuron circuit 130 may include a plurality of neurons connected to the synapse circuit 120. The neuron circuit 130 may receive results in which weights are applied to the input spike signals in the synapse circuit 120. The neuron circuit 130 may perform a function of receiving a signal output from another neuron in a manner similar to a dendrite of the biological neural network. The neuron circuit 130 may compare a value determined by weights output from the synapse circuit 120 with a reference value.

For example, the neuron circuit 130 may compare an accumulated sum of the output results of the synapse circuit 120 with the reference value (or a threshold value). When the accumulated sum exceeds the reference value, the neuron circuit 130 may generate output spike signals (i.e., fire of the neuron). The output spike signals of the neuron circuit 130 may be provided back to the axon circuit 110, may output to the outside of the spiking neural network circuit 100, or may output to other components of the spiking neural network circuit 100.

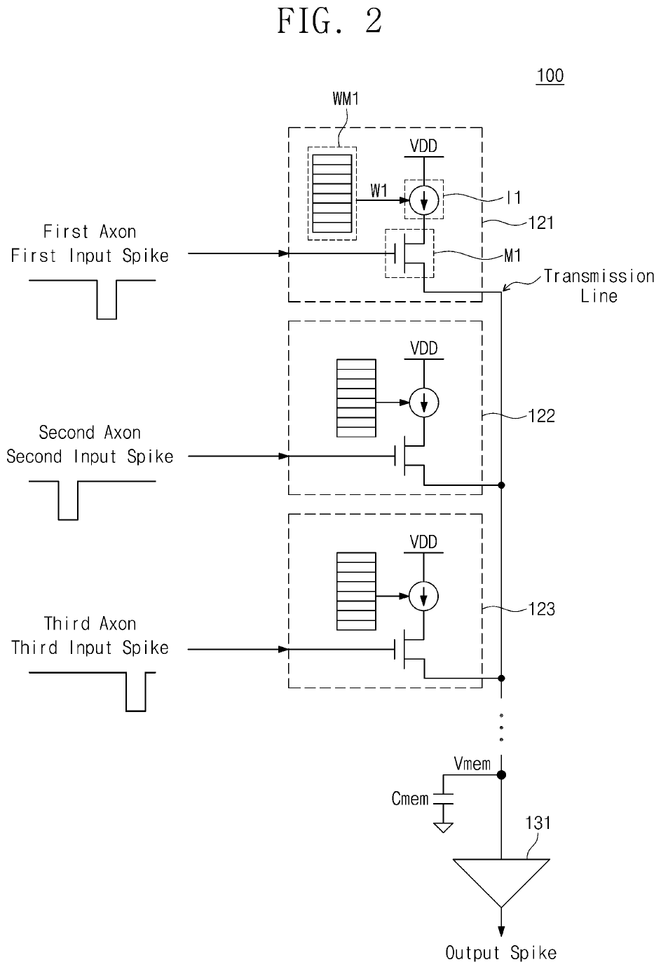

FIG. 2 is a block diagram illustrating synapses connected to one transmission line in more detail, according to some embodiments of the present disclosure. For convenience of description, illustration of the axon circuit 110 is omitted, only some synapses 121, 122, and 123 of the synapse circuit 120 are illustrated, and one neuron 131 of the neuron circuit 130 is illustrated in FIG. 2. FIG. 2 may be a block diagram for describing that input spike signals output from a plurality of axons are transferred to the synapses 121 to 123 for the operation of the neuron 131.

Referring to FIGS. 1 and 2, the synapses 121, 122, and 123 may be connected to the neuron 131 through a transmission line. The synapse 121 may receive a first input spike signal from a first axon of the axon circuit 110, the synapse 122 may receive a second input spike signal from a second axon of the axon circuit 110, and the synapse 123 may receive a third input spike signal from a third axon of the axon circuit 110. The first to third input spike signals may be active low signals. For example, the first to third input spike signals may include negative level pulses (e.g., spikes corresponding to logic ‘0’).

The synapse 121 may include a current source Il, a transistor M1, and a weight memory WM1. The weight memory WM1 may store a weight bit corresponding to a weight W1. In some embodiments, the weight memory WM1 may include a register or a memory cell (e.g., a static random access memory (SRAM) cell, a dynamic random access memory (DRAM) cell, a latch, a NAND flash memory cell, a NOR flash memory cell, a resistive random access memory (RRAM) cell, a ferroelectric random access memory (FRAM) cell, a phase change random access memory (PRAM) cell, a magnetic random access memory (MRAM) cell, etc.). The weight memory WM1 may provide a digital signal corresponding to the weight W1 to the current source Il.

In some embodiments, the synapse 121 may further include a digital to analog converter (DAC) (not illustrated). The weight bit stored in the weight memory WM1 may be converted into an analog signal (e.g., a voltage or a current signal) corresponding to the weight W1 by the DAC of the synapse 121. The DAC may provide the analog signal corresponding to the weight W1 to the current source Il.

In some embodiments, the weight memory WM1 and the DAC described above may be included in a semiconductor device in which the spiking neural network circuit 100 is implemented, but may be separated from the synapse circuit 120. In these embodiments, the DACs separated from the synapse circuit 120 may transmit weight voltages to the synapse circuit 120, or the weight memories may transmit the weight bits to the synapse circuit 120.

The current source Il may receive a signal corresponding to the weight W1 and may generate a current corresponding to a first weight. In some embodiments, the current source Il may include a transistor (e.g., a PMOS) connected between the power supply voltage VDD and the transistor M1. The transistor of the current source Il may receive a signal corresponding to the weight W1 from the weight memory WM1 (or from the DAC) through a gate terminal. A first terminal (e.g., a source) of the transistor of the current source Il may be connected to the power supply voltage VDD. A second terminal (e.g., a drain) of the transistor of the current source Il may be connected to a first terminal (e.g., a source) of the transistor M1. The current source Il may output a current corresponding to the weight W1 to the transistor M1. The current output from the current source Il may correspond to an operation result of the synapse 121.

The transistor M1 may receive the first input spike signal (a first input spike; for example, a negative pulse signal) through a gate terminal. The first terminal of the transistor M1 may be connected to the current source Il. A second terminal (e.g., a drain) of the transistor M1 may be connected to a transmission line. The transistor M1 may be a switch that is turned on or turned off depending on the first input spike signal. When the transistor M1 is turned on depending on the first input spike signal, the transistor M1 may output the current output, that is, the operation signal, from the current source Il depending on the first input spike signal to the transmission line. The first synapse 121 may generate a first operation signal based on the first input spike signal and the weight W1. The magnitude of the first operation signal may be determined by a product of the first input spike signal and the weight W1. For example, the first operation signal may be a current signal corresponding to the product of the first input spike signal and the weight W1. In some embodiments, the transistor M1 may be implemented with a PMOS, an NMOS, or a combination of the PMOS and the NMOS.

The synapses 122 and 123 may be implemented in a similar manner to the synapse 121, and may operate in a similar manner to the synapse 121. For example, the synapse 122 may receive a second input spike signal (a second input spike) from the second axon of the axon circuit 110. The synapse 122 may generate a second operation signal based on the weight of the synapse 122 and the second input spike signal. The synapse 123 may receive a third input spike signal (a third input spike) from the third axon of the axon circuit 110. The synapse 123 may generate a third operation signal based on the weight of the synapse 123 and the third input spike signal. The weights of the synapses 121 to 123 may be the same or different from one another.

The first to third input spike signals may have a relatively low voltage level during a relatively short period and a relatively high voltage level during the remaining period. While the first to third input spike signals are not activated (that is, during a period in which the first to third input spike signals have a relatively high voltage level), transistors (e.g., M1) of the synapses 121 to 123 may be in a turned-off state. The first to third input spike signals may be the same as or different from one another.

The neuron circuit 130 may include a capacitor Cmem and the neuron 131 which are connected to the synapses 121 to 123. The capacitor Cmem may be charged by the first to third operation signals output from the synapses 121 to 123. A level of a voltage Vmem of the capacitor Cmem may correspond to an amount of charges accumulated depending on the first to third operation signals. The voltage Vmem of the capacitor Cmem may be provided to the neuron 131. The capacitor Cmem may be referred to as a membrane capacitor.

In some embodiments, the spiking neural network circuit 100 may further include a discharge circuit (not illustrated) that periodically or aperiodically discharges the capacitor Cmem. Before the first to third operation signals output from the synapses 121 to 123 depending on the first to third input spike signals are input to the capacitor Cmem, the discharge circuit may fully discharge the capacitor Cmem.

In some embodiments, the neuron circuit 130 may further include capacitors in which charges are accumulated by operation signals output from synapses.

The neuron 131 may compare the magnitude of the first to third operation signals output from the synapses 121 to 123 and a reference value (or a threshold). For example, the neuron 131 may compare the voltage Vmem of the capacitor Cmem with the reference voltage. The neuron 131 may generate an output spike signal based on the comparison result. For example, when the voltage Vmem of the capacitor Cmem is greater than the reference voltage, the neuron 131 may output the output spike signal (i.e., fire).

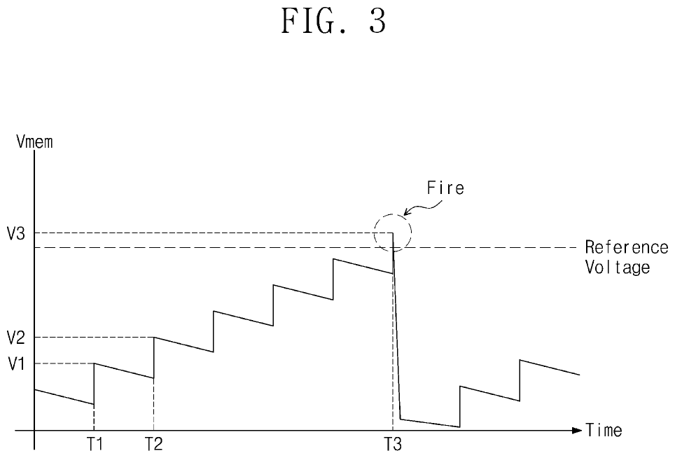

FIG. 3 is a graph illustrating a change in the voltage Vmem over time, according to some embodiments of the present disclosure. Referring to FIGS. 1 to 3, as the operation signals output from synapses (e.g., the synapses 121 to 123) are accumulated in the capacitor Cmem, a level of the voltage Vmem may gradually increase over time.

At time t1, in response to the input spike signal, a transistor of any one synapse among synapses (e.g., the synapses 121 to 123) connected to the capacitor Cmem may be turned on. Accordingly, the operation signal based on the input spike signal and the weight of the synapse may be output from the synapse to the capacitor Cmem. Charges corresponding to the operation signal may be charged in the capacitor Cmem. As a result, the level of the voltage Vmem may rise to a voltage V1.

Between time t1 and time t2, the voltage Vmem charged in the capacitor Cmem may drop slightly. For example, some charges charged in the capacitor Cmem may leak, and accordingly, the voltage Vmem may drop.

At time t2, in a manner similar to that at time t1, in response to the input spike signal, a transistor of any one of the synapses connected to the capacitor Cmem may be turned on. Accordingly, an operation signal based on input spike signal and the weight of the synapse may be output from the synapse to the capacitor Cmem. Charges corresponding to the output operation signal may be charged in the capacitor Cmem. As a result, a level of voltage Vmem may rise to a voltage V2.

Between time t2 and time t3, a level of the voltage Vmem may gradually rise in response to input spike signals input to the synapses.

At time t3, in response to the operation signal output from the synapse, a level of the voltage Vmem may rise to a voltage V3. A level of the voltage V3 may be greater than a level of the reference voltage. The neuron 131 may output the output spike signal in response to that the level of the voltage Vmem is greater than that of the reference voltage (that is, the neuron 131 may fire). Thereafter, the capacitor Cmem may be discharged to a voltage close to a ground voltage by the discharge circuit.

In the embodiment of FIG. 3, the voltage Vmem also repeats rising and falling at uniform intervals depending on the input spike signals having a uniform interval and a uniform pulse width, but the present disclosure is not limited thereto. For example, the interval between the preceding input spike signal and the following input spike signal may not be uniform. The pulse width of the preceding input spike signal and a pulse width of the following input spike signal may not be the same.

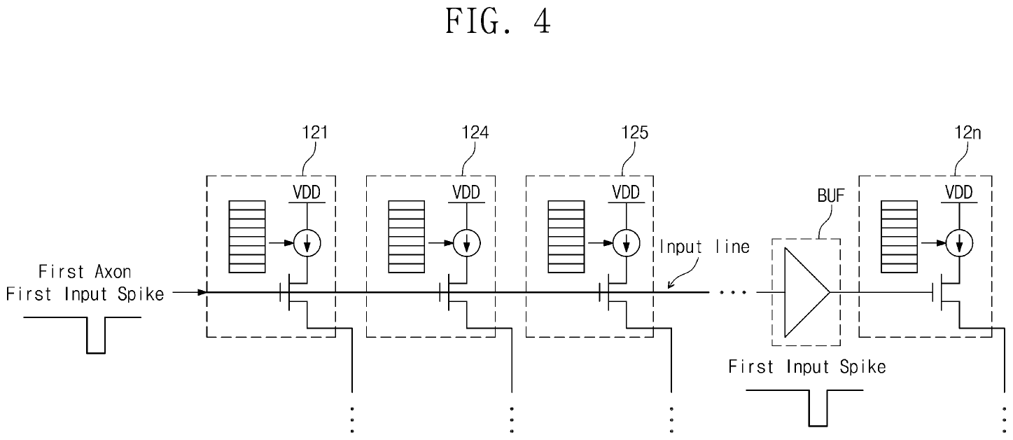

FIG. 4 illustrates synapses that receive one input spike signal in more detail, according to some embodiments of the present disclosure. Referring to FIGS. 1 to 4, synapses 121, 124, 125, and 12n (‘n’ may be a natural number) may receive the first input spike signal (first input spike) from the first axon of the axon circuit 110 through an input line (or a driving line).

To ensure an accuracy of firing of the neurons of the neuron circuit 130, a shape and a pulse width of the first input spike signal may need to be transferred to the synapses 121, 124, 125, and 12n actually the same. For example, when the first input spike signal is distorted and transferred to the synapse 121, the magnitude of the first operation signal output from the synapse 121 may also be distorted. Accordingly, the amount of charge charged in the capacitor Cmem connected to the synapse 121 in response to the first input spike signal may be different from an amount of charge to be charged in the capacitor Cmem when the first input spike signal is not distorted. As a result, in response to the first input spike signal, the neuron 131 may not fire even when the neuron should fire, or may fire even when the neuron should not fire.

When a length of the input line increases or the number of synapses receiving the first input spike signal from the first axon increases, the first input spike signal transferred to some synapses may be distorted. For example, a quality of the pulse of the first input spike signal may be deteriorated due to passing through a plurality of synapses (e.g., synapses 121, 124, and 125). As a result, the shape of the first input spike signal transferred to a synapse (e.g., synapse 121) relatively close to the first axon may be different from the shape of the first input spike signal transferred to a synapse (e.g., synapse 12n) relatively distant to the first axon.

To prevent a distortion of the first input spike signal, a driving buffer BUF may be inserted into the input line. The driving buffer BUF may receive the first input spike signal through the input line. The driving buffer BUF may buffer the received first input spike signal. The driving buffer BUF may output the buffered first input spike signal to the transistor of the synapse 12n. Accordingly, the distortion of the first input spike signal transferred to the synapse 12n may be prevented.

In the embodiment of FIG. 4, only one driving buffer BUF is illustrated for convenience of illustration, but a plurality of driving buffers may be inserted into one input line. The number of driving buffers inserted into the input line may be determined based on a length of the input line connected to one axon or the number of synapses connected to one axon. For example, the number of driving buffers inserted into the input line may increase as a scale of the spiking neural network circuit 100 increases, for example, as the number of synapses increases. In some embodiments, the driving buffer may be inserted into the input line every 5 synapses to every 10 synapses.

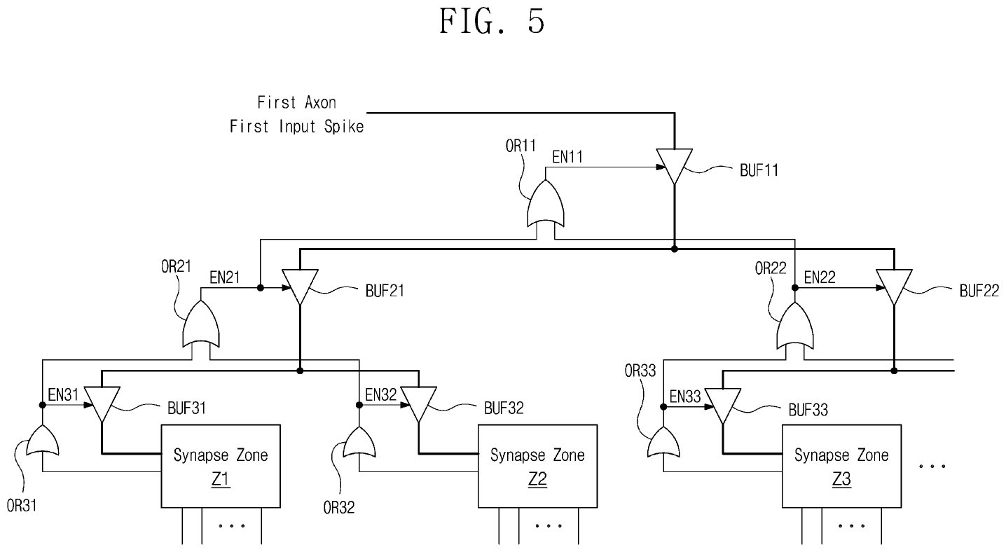

FIG. 5 illustrates a hierarchical structure of synapses that receive one input spike signal, according to some embodiments of the present disclosure. Referring to FIGS. 1 to 5, in contrast to the embodiment of FIG. 4, in the embodiment of FIG. 5, the first input spike signal may be input to synapses, based on a hierarchical structure. For example, the input line that transfers the first input spike signal to the synapses may be implemented with the hierarchical structure of a tree structure. A branch node (vertex) of each tree may include a driving buffer that outputs the first input spike signal to a lower layer.

One driving buffer may have a plurality of lower driving buffers. One lower driving buffer may again have a plurality of lower driving buffers. For example, a driving buffer BUF11 may have two lower driving buffers BUF21 and BUF22. The driving buffer BUF21 may have two lower driving buffers BUF31 and BUF32 again. The driving buffer BUF22 may have lower driving buffers (e.g., a buffer BUF33) again.

The driving buffers of the lowest layer may be connected to a corresponding synapse zone. The driving buffers of the lowest layer may transfer the input spike signal received through upper layers to the corresponding synapse zone. For example, in the illustrated embodiment, the lowest layer may be a layer to which the buffers BUF31, BUF32, and BUF33 belong. The buffer BUF31 may be connected to a synapse zone Z1, the buffer BUF32 may be connected to a synapse zone Z2, and the buffer BUF33 may be connected to a synapse zone Z3. The buffers BUF31, BUF32, and BUF33 may transfer the first input spike signal transferred from the upper layers to the corresponding synapse zone.

A binary tree structure in which one driving buffer has two lower driving buffers is illustrated in FIG. 5, but the present disclosure is not limited thereto. For example, one upper driving buffer may have two or more lower driving buffers.

For convenience of illustration, in the embodiment of FIG. 5, the input line includes three layers (stages, or steps), but the present disclosure is not limited thereto. For example, the input line may include two layers or four or more layers.

One driving buffer may have a corresponding one OR gate. For example, the driving buffer BUF11 may have a corresponding OR gate OR11. The OR gate OR11 may receive enable signals EN21 and EN22 from OR gates OR21 and OR22 corresponding to the lower driving buffers BUF21 and BUF22 of the driving buffer BUF11, respectively. The OR gate OR11 may output an enable signal EN11 to the driving buffer BUF11, based on the received enable signals EN21 and EN22. For example, the OR gate OR11 may perform an OR operation on the received enable signals EN21 and EN22, and may output the operation result as the enable signal EN11. In response to that both the enable signals EN21 and EN22 of the lower layer are logic ‘0’, the OR gate OR11 may output the enable signal EN11 corresponding to the logic ‘0’. In response to that at least one of the enable signals EN21 and EN22 of the lower layer is logic ‘1’, the OR gate OR11 may output the enable signal EN11 corresponding to the logic ‘1’.

The driving buffer BUF11 may be activated (or turned on) or deactivated (or turned off) in response to the enable signal EN11. For example, in response to the enable signal EN11 corresponding to the logic ‘1’, the driving buffer BUF11 may be activated and may transfer the first input spike signal to the lower driving buffers BUF21 and BUF22. In response to the enable signal EN11 corresponding to logic ‘0’, the driving buffer BUF11 may be deactivated, and may not transfer the first input spike signal to the lower driving buffers BUF21 and BUF22. For example, the deactivated driving buffer BUF11 may output a signal corresponding to the logic ‘1’ to the lower driving buffers BUF21 and BUF22. As the driving buffer BUF11 is deactivated, the first input spike signal may not be transferred to the lower driving buffers (e.g., the driving buffers BUF31, BUF32, and BUF33) of the lower driving buffers BUF21 and BUF22. Accordingly, in response to the enable signal EN11, the driving buffer BUF11 may selectively transfer the first input spike signal to the lower layer.

In a similar manner to the driving buffer BUF11, the driving buffer BUF21 may be activated or deactivated based on enable signals EN31 and EN32 of the driving buffers BUF31 and BUF32 of the lower layer. The driving buffer BUF22 may be activated or deactivated based on enable signals (e.g., an enable signal EN33) of the driving buffers (e.g., the driving buffer BUF33) of the lower layer.

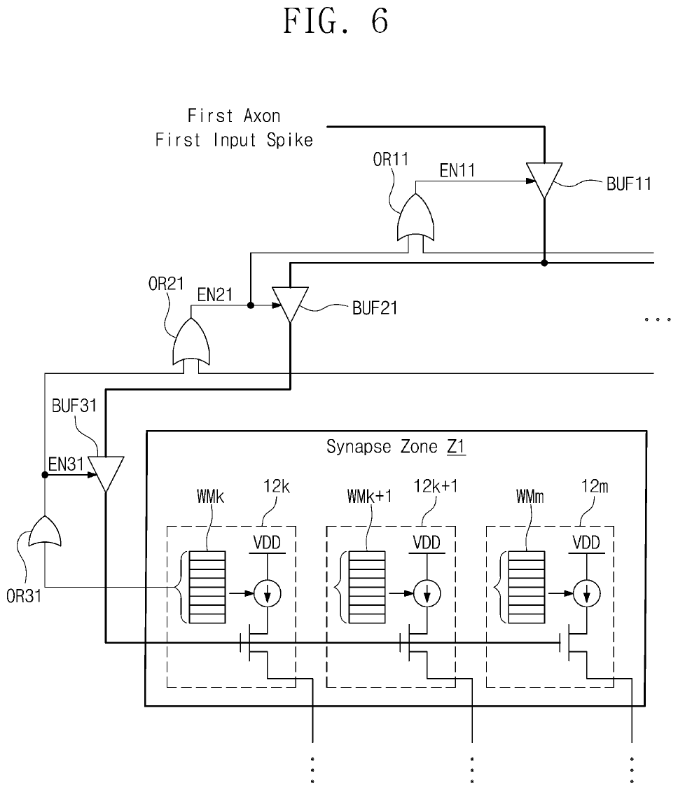

OR gates of the lowest layer may output an enable signal based on weights of synapses of a corresponding synapse zone. For example, an OR gate OR31 may receive weights of synapses of the synapse zone Z1, and may output the enable signal EN31 based on the received weights. An operation of the OR gate OR31 will be described in detail later with reference to FIG. 6.

The synapse zones Z1, Z2, and Z3 include at least one of synapses (e.g., synapses 121, 124, 125, and 12n) that receive the first input spike signal from the first axon. Since the first input spike signal is selectively transferred from the upper layer to the lower layer, only some of the synapse zones Z1, Z2, and Z3 may receive the first input spike signal. Accordingly, power consumption due to transfer of the first input spike signal may be reduced.

For example, in response to that the enable signal EN31 output from the OR gate OR31 corresponds to the logic ‘0’, the driving buffer BUF31 may be deactivated. As a result, the first input spike signal may not be transferred to the synapse zone Z1. Accordingly, power consumption due to the transfer of the first input spike signal may be reduced.

FIG. 6 illustrates the synapse zone Z1 of FIG. 5 in more detail, according to some embodiments of the present disclosure. Referring to FIGS. 1 to 6, the synapse zone Z1 may include synapses 12k, 12k+1, . . . , 12m (where ‘k’ and ‘m’ may be natural numbers). The number of synapses included in the synapse zone Z1 is not limited to the illustrated embodiment.

The OR gate OR31 may receive weight bits from weight memories WMk, WMk+1, WMm of the synapses 12k, 12k+1, . . . , 12m of synapse zone Z1. The OR gate OR31 may perform an OR operation on the received weight bits. In response to that the weights of all synapses 12k, 12k+1, . . . , 12m of the synapse zone Z1 are ‘0’, the OR gate OR31 may output the enable signal EN31 corresponding to the logic ‘0’. In response to that at least one of the weights of the synapses 12k, 12k+1, . . . , 12m of the synapse zone Z1 are not ‘0’, the OR gate OR31 may output the enable signal EN31 corresponding to the logic ‘1’.

In a synapse of which the weight is ‘0’, even if the first input spike signal is received, an operation between the first input spike signal and the weight may not be performed. For example, it is assumed that the weight of the synapse 12k corresponding to weight bits stored in the weight memory WMk corresponds to ‘0’. In this case, in the synapse 12k, an operation for applying a weight to the first input spike signal may not be performed. For example, the current output from the current source of the synapse 12k, that is, the operation signal of the synapse 12k may correspond to ‘0’. Accordingly, it may not be necessary for the first input spike signal to be applied to the transistor of the synapse 12k.

Similar to as described above, when the weights of the synapses 12k, 12k+1, . . . , 12m of the synapse zone Z1 are all ‘0’, the first input spike signal may not need to be applied to the synapse zone Z1. In this case, the enable signal EN31 corresponding to the logic ‘0’ may be output from the OR gate OR31. In response to the enable signal EN31 corresponding to the logic ‘0’, the driving buffer BUF31 may be deactivated. Therefore, the first input spike signal may not be transferred to the synapse zone Z1. As the first input spike signal is not transferred to synapses that do not require the transfer of the first input spike signal, the power consumed in the driving buffers of the input line due to the transfer of the first input spike signal may be reduced while ensuring the performance of the spiking neural network circuit 100.

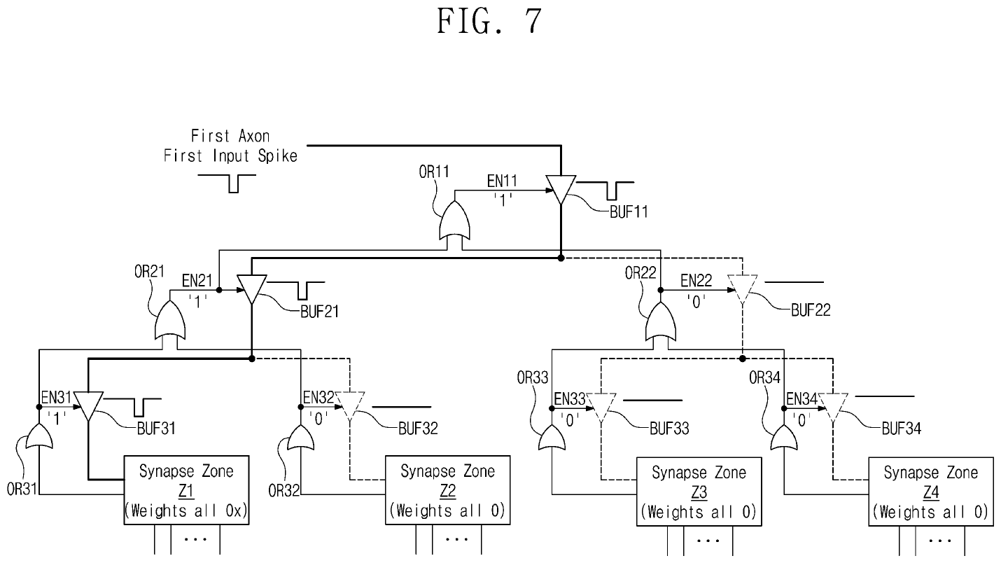

FIG. 7 illustrates an operation in which one input spike signal is transferred to a plurality of synapses, according to some embodiments of the present disclosure. Referring to FIGS. 1 to 7, the driving buffer BUF22, which is the lower driving buffer of the driving buffer BUF11, may include two lower driving buffers BUF33 and BUF34. The driving buffer BUF34 may be connected to a synapse zone Z4. The driving buffer BUF34 may include an OR gate OR34 outputting an enable signal EN34.

The first input spike signal may be input from the first axon to the driving buffer BUF11 of the uppermost layer. Based on the enable signal EN11 output from the OR gate OR11, it may be determined whether the driving buffer BUF11 transfers the first input spike signal to the driving buffers BUF21 and BUF22 of the lower layer.

The enable signal EN11 may be determined based on the enable signals EN21 and EN22 of the lower layer. The enable signal EN21 of the lower layer may be determined based on the enable signals EN31 and EN32 of its lower layer. The enable signal EN22 of the lower layer may be determined based on the enable signals EN33 and EN34 of its lower layer.

In a left tree of the driving buffer BUF11, the weight of at least some of the synapses of the synapse zone Z1 may not be ‘0’. Accordingly, the enable signal EN31 output from the OR gate OR31 may correspond to the logic ‘1’. In response to the enable signal EN31 corresponding to the logic ‘1’, the driving buffer BUF31 may be activated.

In contrast, the weights of the synapses of the synapse zone Z2 may be all ‘0’. Accordingly, the enable signal EN32 output from an OR gate OR32 may correspond to the logic ‘0’. In response to the enable signal EN32 corresponding to the logic ‘0’, the driving buffer BUF32 may be deactivated.

The OR gate OR21 may receive the enable signals EN31 and EN32. In response to the enable signal EN31 corresponding to the logic ‘1’ and the enable signal EN32 corresponding to the logic ‘0’, the enable signal EN21 output from the OR gate OR21 may correspond to the logic ‘1’. In response to the enable signal EN21 corresponding to the logic ‘1’, the driving buffer BUF21 may be activated.

In a right tree of the driving buffer BUF11, the weights of the synapses of the synapse zone Z3 and the weights of the synapses of the synapse zone Z4 may be all ‘0’. Accordingly, the enable signal EN33 output from the OR gate OR33 and the enable signal EN34 output from the OR gate OR34 may correspond to the logic ‘0’. In response to the enable signal EN33 corresponding to the logic ‘0’, the driving buffer BUF33 may be deactivated. In response to the enable signal EN34 corresponding to the logic ‘0’, the driving buffer BUF34 may be deactivated.

The OR gate OR22 may receive the enable signals EN33 and EN34. In response to the enable signal EN33 corresponding to the logic ‘0’ and the enable signal EN34 corresponding to the logic ‘0’, the enable signal EN22 output from the OR gate OR22 may correspond to the logic ‘0’. In response to the enable signal EN22 corresponding to the logic ‘0’, the driving buffer BUF22 may be deactivated.

The OR gate OR11 of the uppermost layer may receive the enable signals EN21 and EN22. In response to the enable signal EN21 corresponding to the logic ‘1’ and the enable signal EN22 corresponding to the logic ‘0’, the enable signal EN11 output from the OR gate OR11 may correspond to the logic ‘1’. In response to the enable signal EN11 corresponding to the logic ‘1’, the driving buffer BUF11 may be activated.

Since the driving buffer BUF21 is activated and the driving buffer BUF22 is deactivated, the first input spike signal is transferred to the left tree of the driving buffer BUF11 through the driving buffer BUF11, but the first input spike signal is not transferred to the right tree of the driving buffer BUF11. For example, the outputs of the driving buffer BUF22 and its lower driving buffers BUF33 and BUF34 may maintain the logic ‘1’. Accordingly, the synapses of the synapse zone Z3 connected to the driving buffer BUF33 and the synapses of the synapse zone Z4 connected to the driving buffer BUF34 may not perform an operation on the first input spike signal.

In contrast, the driving buffer BUF21 may receive the first input spike signal from the driving buffer BUF11. Since the driving buffer BUF31 is activated and the driving buffer BUF32 is deactivated, the first input spike signal is transferred to the left tree of the driving buffer BUF21 through the driving buffer BUF21, but the first input spike signal is not transferred to the right tree of the driving buffer BUF21. For example, the output of the driving buffer BUF32 may maintain the logic ‘1’. Accordingly, the synapses of the synapse zone Z2 connected to the driving buffer BUF32 may not perform an operation on the first input spike signal.

The driving buffer BUF31 may receive the first input spike signal from the driving buffer BUF21. The driving buffer BUF31 may transfer the first input spike signal to the synapses of the synapse region Z1. The synapses of the synapse zone Z1 may perform an operation based on respective weights with respect to the first input spike signal. The operation results of synapses in the synapse zone Z1 may be transferred to the neuron circuit 130.

Since the weights of the synapses of the synapse zones Z2, Z3, and Z4 are all ‘0’, even if the first input spike signal is received, the synapses of the synapse zones Z2, Z3, and Z4 may not perform an operation on the first input spike signal. Accordingly, it may not be necessary to transfer the first input spike signal to the synapse zones Z2, Z3, and Z4. As the driving buffers BUF32, BUF33, and BUF34 are deactivated, the first input spike signal may not be transferred to the synapse zones Z2, Z3, and Z4 that do not require the input of the first input spike signal. As a result, the current consumed in the transfer of the first input spike signal may be minimized.

According to an embodiment of the present disclosure, one input spike signal may be transferred to synapses through a hierarchical structure of driving buffers. One input spike signal may be selectively transferred to the synapses based on the weights of the synapses. The driving buffers may be activated or deactivated based on the weights of the synapses. Accordingly, power consumed to transfer the input spike signal may be reduced.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A spiking neural network circuit comprising:
an axon circuit which generates an input spike signal;
a first synapse zone and a second synapse zone each including one or more synapses, wherein each of the synapses performs an operation based on the input spike signal and each weight; and
a neuron circuit which generates an output spike signal based on operation results of the synapses, and
wherein the input spike signal is transferred to the first synapse zone and the second synapse zone through a tree structure, and
wherein each of branch nodes of the tree structure includes a driving buffer.

2. The spiking neural network circuit of claim 1, wherein the tree structure includes OR gates which outputs an enable signal to a corresponding driving buffer.

3. The spiking neural network circuit of claim 1, wherein the tree structure includes a first layer, a second layer, and a first OR gate,
wherein the first layer includes a first driving buffer which receives the input spike signal, and
wherein the first OR gate outputs a first enable signal to the first driving buffer based on enable signals output from the second layer.

4. The spiking neural network circuit of claim 3, wherein the second layer includes:
a second driving buffer including an input terminal connected to an output terminal of the first driving buffer and an output terminal connected to the first synapse zone; and
a third driving buffer including an input terminal connected to the output terminal of the first driving buffer and an output terminal connected to the second synapse zone, and
wherein the tree structure includes:
a second OR gate which outputs a second enable signal to the second driving buffer; and
a third OR gate which outputs a third enable signal to the third driving buffer.

5. The spiking neural network circuit of claim 4, wherein the second OR gate receives weights of synapses of the first synapse zone, and outputs the second enable signal based on the weights of the synapses of the first synapse zone.

6. The spiking neural network circuit of claim 4, wherein the second driving buffer is activated or deactivated in response to the second enable signal,
wherein, when the second driving buffer is activated, the second driving buffer transfers the input spike signal received from the first driving buffer to the synapses of the first synapse zone, and
wherein, when the second driving buffer is deactivated, the second driving buffer transfers a signal corresponding to a first logic to the synapses of the first synapse zone.

7. The spiking neural network circuit of claim 4, wherein a first synapse of the first synapse zone includes a current source which outputs a current signal based on a weight of the first synapse and a transistor which receives the current signal, and
wherein an output terminal of the second driving buffer is connected to a gate of the transistor of the first synapse.

8. The spiking neural network circuit of claim 7, wherein the second driving buffer transfers the input spike signal to the gate of the transistor of the first synapse in response to the second enable signal, and
wherein the transistor is turned on in response to the input spike signal and outputs the current signal to the neuron circuit.

9. The spiking neural network circuit of claim 4, wherein the first OR gate outputs the first enable signal to the first driving buffer, based on the second enable signal and the third enable signal,
wherein, the first driving buffer is activated or deactivated in response to the first enable signal,
wherein, when the first driving buffer is activated, the first driving buffer transfers the input spike signal to the second driving buffer and the third driving buffer, and
wherein, when the first driving buffer is deactivated, the first driving buffer transfers a signal corresponding to a first logic to the second driving buffer and the third driving buffer.

10. A spiking neural network circuit comprising:
an axon circuit which generates an input spike signal;
synapse zones each including one or more synapses, wherein each of the synapses performs an operation based on the input spike signal and each weight; and
a neuron circuit which generates an output spike signal based on operation results of the synapses, and
wherein the input spike signal is selectively transferred to at least some of the synapse zones based on weights of the synapses through a tree structure.

11. The spiking neural network circuit of claim 10, wherein each of branch nodes of the tree structure includes a driving buffer which receives the input spike signal from a driving buffer of an upper layer and transfers the input spike signal to driving buffers of a lower layer in response to an enable signal, and
wherein the tree structure includes OR gates which generate a corresponding enable signal to a corresponding driving buffer.

12. The spiking neural network circuit of claim 10, wherein the tree structure includes a first layer and a second layer,
wherein the second layer includes a first branch node corresponding to a first synapse zone of the synapse zones and a second branch node corresponding to a second synapse zone of the synapse zones,
wherein the first branch node includes a first driving buffer which transfers the input spike signal transferred from the first layer to the first synapse zone in response to a first enable signal, and
wherein the first enable signal is based on weights of synapses of the first synapse zone.

13. The spiking neural network circuit of claim 12, wherein the first enable signal corresponds to a logic low in response to weights of all synapses in the first synapse zone being ‘0’, and corresponds to a logic high in response to at least one of the weights of the synapses in the first synapse zone being non-zero.

14. The spiking neural network circuit of claim 13, wherein the first driving buffer is deactivated in response to the first enable signal corresponding to the logic low, and transfers the input spike signal to the first synapse zone in response to the first enable signal corresponding to the logic high.

15. The spiking neural network circuit of claim 12, wherein the second branch node includes a second driving buffer which transfers the input spike signal transferred from the first layer to the second synapse zone in response to a second enable signal,
wherein the second enable signal is based on weights of synapses in the second synapse zone,
wherein the first layer includes a third branch node connected to the first branch node and the second branch node,
wherein the third branch node includes a third driving buffer which transfers the input spike signal to the first driving buffer and the second driving buffer in response to a third enable signal, and
wherein the third enable signal is based on the first enable signal and the second enable signal.

16. The spiking neural network circuit of claim 15, wherein the third enable signal corresponds to a logic high in response to that at least one of the first enable signal and the second enable signal corresponds to the logic high, and corresponds to a logic low in response to that both the first enable signal and the second enable signal correspond to the logic low, and
wherein the third driving buffer is deactivated in response to the third enable signal corresponding to the logic low, and transfers the input spike signal to the second branch node and the third branch node in response to the third enable signal corresponding to the logic high.
